(19) United States
(12) Patent Application Publication
(10) Pub. No.: US 2025/0379138 A1
(43) Pub. Date: Dec. 11, 2025

(54) SEMICONDUCTOR DEVICE

(71) Applicant: DENSO CORPORATION, Kariya-city (JP)

(72) Inventors: Ryoji UWATAKI, Kariya-city (JP); Tomomi OKUMURA, Kariya-city (JP)

(21) Appl. No.: 19/229,246

(22) Filed: Jun. 5, 2025

(30) Foreign Application Priority Data
Jun. 10, 2024 (JP) 2024-093931

(51) Int. Cl. H01L 23/498; H01L 23/00; H01L 23/31; H01L 23/373; H01L 23/538; H01L 25/065

(52) U.S. Cl. CPC H01L 23/49894; H01L 23/3121; H01L 23/3737; H01L 23/5386; H01L 24/32; H01L 25/0655; H01L 24/26; H01L 2224/2612; H01L 2224/32227; H01L 2924/3511

(57) ABSTRACT

A semiconductor device includes a substrate, a semiconductor element and a resin molded body, and a fragile layer. The substrate includes an insulating base material containing a resin, a front-surface metal body on a front surface of the insulating base material, and a back-surface metal body on a back surface of the insulating base material. The semiconductor element is electrically connected to the front-surface metal body. The resin molded body encapsulates the substrate and the semiconductor element. The insulating base material has an exposed surface exposed from the front-surface metal body. The fragile layer is stacked on at least a part of the exposed surface and interposed between the insulating base material and the resin molded body. The fragile layer has a yield point lower than that of the insulating base material.

### CROSS REFERENCE TO RELATED APPLICATION

The present application claims the benefit of priority from Japanese Patent Application No. 2024-093931 filed on Jun. 10, 2024. The entire disclosures of the above application are incorporated herein by reference.

### TECHNICAL FIELD

The present disclosure relates to a semiconductor device.

### BACKGROUND

Patent literature 1 (WO2017/119226A1, which corresponds to US2019/0006255A1) discloses a semiconductor device including a substrate, a semiconductor element, and a resin molded body. The substrate includes an insulating layer (insulating base material), a wiring disposed on a front surface of the insulating layer and a heat dissipation layer disposed on a back surface of the insulating layer. The semiconductor element is connected to the wiring of the substrate. The resin molded body encapsulates the substrate and the semiconductor element. The disclosure of the patent literature 1 is incorporated herein by reference as an explanation of technical elements in the present disclosure.

### SUMMARY

According to an aspect of the present disclosure, a semiconductor device includes a substrate, a semiconductor element and a resin molded body. The substrate includes an insulating base material containing a resin, a front-surface metal body disposed on a front surface of the insulating base material patterned, and a back- surface metal body disposed on a back surface of the insulating base material. The semiconductor element has a first main electrode on a first surface and a second main electrode on a second surface opposite to the first surface in a thickness direction of the semiconductor element. The semiconductor element is electrically connected to the front-surface metal body. The resin molded body encapsulates the substrate and the semiconductor element. The insulating base material has an exposed surface exposed from the front-surface metal body. The semiconductor device may further include a fragile layer that is stacked on at least a part of the exposed surface, interposed between the insulating base material and the resin molded body, and has a yield point lower than that of the insulating base material.

### BRIEF DESCRIPTION OF DRAWINGS

Objects, features and advantages of the present disclosure will become more apparent from the following detailed description made with reference to the accompanying drawings, in which:

FIG. 1 is a diagram showing a power conversion circuit and a drive system to which a semiconductor device according to a first embodiment is applied;

FIG. 2 is a perspective view of the semiconductor device;

FIG. 3 is a perspective view, including a cross-section taken along a line III-III in FIG. 2, of the semiconductor device;

FIG. 4 is a cross-sectional view of the semiconductor device;

FIG. 5 is a plan view of a substrate on a drain electrode side;

FIG. 6 is a plan view of a substrate on a source electrode side;

FIG. 7 is an enlarged cross-sectional view of a region VII shown in FIG. 4;

FIG. 8 is a diagram showing the relationship between a stress and a strain of a fragile layer and an insulating base material;

FIG. 9 is a cross-sectional view showing a state in which resin is filled during molding of a resin molded body;

FIG. 10 is an enlarged cross-sectional view of a region X shown in FIG. 9;

FIG. 11 is a cross-sectional view showing contraction before a curing treatment during the molding of the resin molded body;

FIG. 12 is an enlarged cross-sectional view of a region XII shown in FIG. 11;

FIG. 13 is a cross-sectional view of a reference example; and

FIG. 14 is a cross-sectional view of a modified example.

### DETAILED DESCRIPTION

In the semiconductor device of the patent literature 1, the insulating base material is partly exposed from the wiring. For example, the insulating base material is exposed between a wiring connected to an upper arm IGBT and a wiring connected to a lower arm IGBT. In a case where the insulating base material is made of a resin, when the resin molded body is in close contact with the insulating base material, an insulation distance can be ensured by solid insulation.

When a resin molded body is formed, a curing treatment such as heating is required to complete the reaction of unreacted parts. The resin molded body is completely cured by the curing treatment, and a linear expansion coefficient of the resin molded body after the curing treatment becomes smaller than that before the curing treatment. Before the curing treatment, the linear expansion coefficient of the resin molded body is greater than those of the wiring and the insulating base material containing the resin. Therefore, when the temperature of the resin before the curing treatment drops, that is, when the resin molded body contracts, there is a fear that thermal stress will concentrate at a triple junction of the insulating base material, the wiring, and the resin molded body. From the above-described viewpoint or from other viewpoints not mentioned, further improvement is required for the semiconductor device.

The present disclosure provides a semiconductor device capable of reducing thermal stress acting on an insulating base material.

According to a first aspect of the present disclosure, a semiconductor device includes: a substrate that includes an insulating base material containing a resin, a front-surface metal body disposed on a front surface of the insulating base material patterned, and a back-surface metal body disposed on a back surface of the insulating base material; a semiconductor element that has a first main electrode on a first surface and a second main electrode on a second surface opposite to the first surface in a thickness direction of the semiconductor element, and is electrically connected to the front-surface metal body; and a resin molded body that encapsulates the substrate and the semiconductor element. The insulating base material has an exposed surface exposed from the front-surface metal body. The semiconductor device further includes a fragile layer that is stacked on at least a part of the exposed surface and interposed between the insulating base material and the resin molded body. The fragile layer has a yield point lower than that of the insulating base material.

In the semiconductor device according to the first aspect, the fragile layer can largely deform beyond the yield point, that is, plastically deform, thereby reducing the thermal stress acting on the insulating base material.

According to a second aspect of the present disclosure, a semiconductor device includes: a substrate that includes an insulating base material containing a resin, a front-surface metal body disposed on a front-surface of the insulating base material and patterned, and a back-surface metal body disposed on a back surface of the insulating base material; a semiconductor element that includes a first main electrode on a first surface and a second main electrode on a second surface opposite to the first surface in a thickness direction of the semiconductor element, and is electrically connected to the front-surface metal body; and a resin molded body that encapsulates the substrate and the semiconductor element. The insulating base material has an exposed surface exposed from the front-surface metal body. The semiconductor device further includes an interposed layer that contains any of polyamideimide, polyamide, and polyimide. The interposed layer is stacked on at least a portion of the exposed surface and disposed between the insulating base material and the resin molded body.

In the semiconductor device according to the second aspect, the interposed layer can plastically deform, thereby reducing the thermal stress acting on the insulating base material.

Hereinafter, multiple embodiments of the present disclosure will be described in detail with reference to the drawings. The same or corresponding elements are denoted by the same reference numerals throughout the embodiments, and descriptions thereof will not be repeated. When only part of the configuration is described in each embodiment, the configuration of another preceding embodiment can be applied to the reset of the configuration. Further, not only the combinations of the configurations explicitly illustrated in the description of the respective embodiments, but also configurations of the embodiments can be partially combined even if they are not explicitly illustrated if there is no problem in such combinations in particular.

### First Embodiment

A semiconductor device of the present embodiment is, for example, applied to a mobile object that uses a rotary electric machine as a drive source. Examples of the mobile object include electric vehicles such as a battery electric vehicle (BEV), a hybrid electric vehicle (HEV), and a plug-in hybrid electric vehicle (PHEV), electric flying objects such as a drone and an electronic vertical take-off and landing aircraft (eVTOL), ships, construction machineries, and agricultural machineries. Hereinafter, examples in which the semiconductor device is applied to a vehicle will be described.

### <Vehicle Drive System>

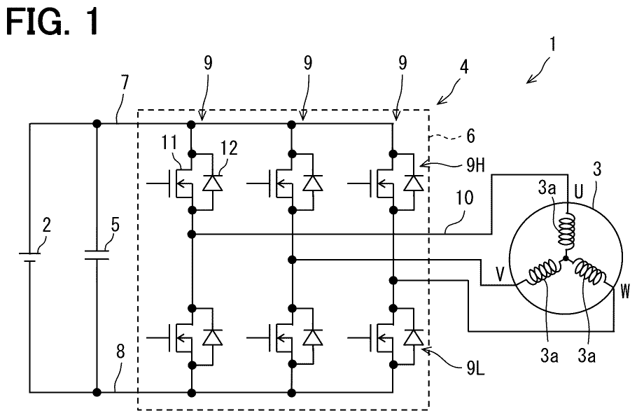

As shown in FIG. 1, a vehicle drive system 1 includes a direct current (DC) power supply 2, a motor generator 3, and a power conversion circuit 4.

The DC power supply 2 is a direct-current voltage source including a chargeable/dischargeable secondary battery. Examples of the secondary battery includes a lithium ion battery, a nickel-metal hydride battery, and the like. The motor generator 3 is a three-phase alternating current (AC) type rotary electric machine. The motor generator 3 functions as a vehicle driving power source, that is, an electric motor. The motor generator 3 functions also as a generator during regeneration. The power conversion circuit 4 performs power conversion between the DC power supply 2 and the motor generator 3.

### <Power Conversion Circuit>

FIG. 1 shows an example of the power conversion circuit 4. The power conversion circuit 4 illustrated in FIG. 1 includes a smoothing capacitor 5 and an inverter 6.

The smoothing capacitor 5 mainly smoothes the DC voltage supplied from the DC power supply 2. The smoothing capacitor 5 is connected between a P-line 7 which is a power line on a high potential side and an N-line 8 which is a power line on a low potential side. The P-line 7 is connected to a positive electrode of the DC power supply 2, and the N-line 8 is connected to a negative electrode of the DC power supply 2. A positive electrode of the smoothing capacitor 5 is connected to the P-line 7 at a position between the DC power supply 2 and the inverter 6. A negative electrode of the smoothing capacitor 5 is connected to the N-line 8 at a position between the DC power supply 2 and the inverter 6. The smoothing capacitor 5 is connected to the DC power supply 2 in parallel.

The inverter 6 corresponds to a DC-AC conversion circuit. The inverter 6 converts the DC voltage into a three-phase AC voltage according to a switching control by a control circuit and outputs the three-phase AC voltage to the motor generator 3. Thereby, the motor generator 3 is driven to generate a predetermined torque. At the time of regenerative braking of the vehicle, the inverter 6 converts the three-phase AC voltage generated by the motor generator 3 by receiving the rotational force from wheels into a DC voltage according to the switching control by the control circuit, and outputs the DC voltage to the P-line 7. In this way, the inverter 6 performs bidirectional power conversion between the DC power supply 2 and the motor generator 3.

The inverter 6 includes upper and lower arm circuits 9 for three phases. The upper and lower arm circuit 9 will also be referred to as a leg. Each of the upper and lower arm circuits 9 has an upper arm 9H and a lower arm 9L. The upper arm 9H and the lower arm 9L are connected in series between the P-line 7 and the N-line 8 with the upper arm 9H being on the P-line 7 side. Hereinafter, the upper arm 9H and the lower arm 9L may be simply referred to as arms 9H and 9L.

A connection point between the upper arm 9H and the lower arm 9L, that is, the midpoint of the upper and lower arm circuit 9 is connected to a winding 3a of a corresponding phase of the motor generator 3 via an output line 10. The inverter 6 has six arms 9H and 9L. Each of the arms 9H and 9L is configured to include a switching element. The number of the switching element constituting each of the arms 9H and 9L is not particularly limited. The number of the switching element constituting each arm may be one or more (for example, two). In a case where each arm is composed of multiple switching elements, the multiple switching elements connected in parallel to one another are turned on and off at the same timing by a common gate drive signal (drive voltage).

The switching element is, for example, an n-channel MOSFET 11. MOSFET is an abbreviation for metal oxide semiconductor field effect transistor. In the upper arm 9H, a drain of the MOSFET 11 is connected to the P-line 7. In the lower arm 9L, a source of the MOSFET 11 is connected to the N-line 8. A source of the MOSFET 11 of the upper arm 9H and a drain of the MOSFET 11 of the lower arm 9L are connected to each other.

A freewheeling diode 12 is connected in anti-parallel to each MOSFET 11. The diode 12 may be a parasitic diode (body diode) of the MOSFET 11 or an external diode. An anode of the diode 12 is connected to the source of a corresponding MOSFET 11. A cathode of the diode 12 is connected to the drain of the corresponding MOSFET 11.

The switching element is not limited to the MOSFET 11. The switching element may be an IGBT. IGBT is an abbreviation for insulated gate bipolar transistor. Also in the case of an IGBT, a freewheeling diode is connected in anti-parallel.

The power conversion circuit 4 may include a converter. The converter is a DC-DC conversion circuit configured to be able to convert a DC voltage into to a DC voltage of a different value, for example. The converter is disposed between the DC power supply 2 and the smoothing capacitor 5. The converter is configured to include, for example, a reactor and the upper and lower arm circuit 9 described above. Such a configuration can boost and/or suppress voltage. The power conversion circuit 4 may include a filter capacitor. The filter capacitor is disposed between the DC power supply 2 and the converter.

The power conversion circuit 4 may include a snubber circuit. The snubber circuit is connected in parallel to the upper and lower arm circuit 9. The snubber circuit reduces the inductance of the upper and lower arm circuit 9. The snubber circuit absorbs a transient high voltage, so-called a switching surge, which occurs when the switching element (MOSFET 11) constituting the upper and lower arm circuit 9 is switched. This enables the inverter 6 to perform high speed switching.

The power conversion circuit 4 may include a drive circuit for the switching elements that constitute the inverter 6 and the like. The drive circuit supplies a drive voltage to the gate of the MOSFET 11 of a corresponding arm based on a drive command of the control circuit. The drive circuit drives the corresponding MOSFET 11 by applying the drive voltage to turn on and off the drive of the corresponding MOSFET 11. The drive circuit will be also referred to as a driver.

The power conversion circuit 4 may include a control circuit for the switching elements. The control circuit generates a drive command for operating the MOSFET 11 and outputs the drive command to the drive circuit. The control circuit generates a drive command based on a torque request input from a host ECU (not illustrated) and signals detected by various sensors. ECU is an abbreviation for electronic control unit.

The various sensors include, for example, a current sensor, a rotation angle sensor, and a voltage sensor. The current sensor detects a phase current flowing through the winding 3a of each phase. The rotation angle sensor detects a rotation angle of a rotor of the motor generator 3. The voltage sensor detects a voltage across the smoothing capacitor 5. The control circuit outputs, for example, a PWM signal as the drive command. The control circuit includes, for example, a processor and a memory. PWM is an abbreviation for pulse width modulation.

### <Semiconductor Device>

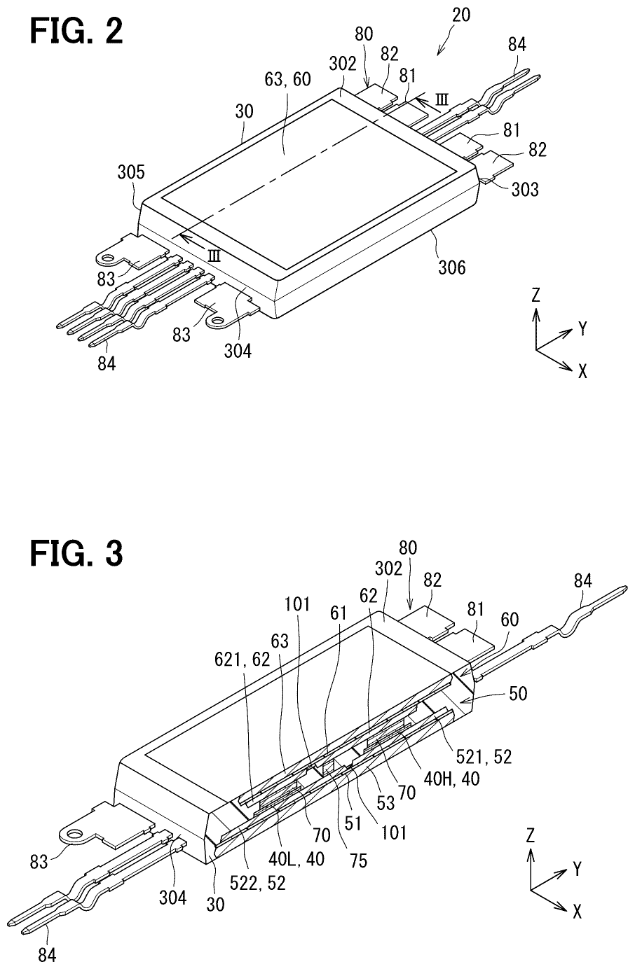

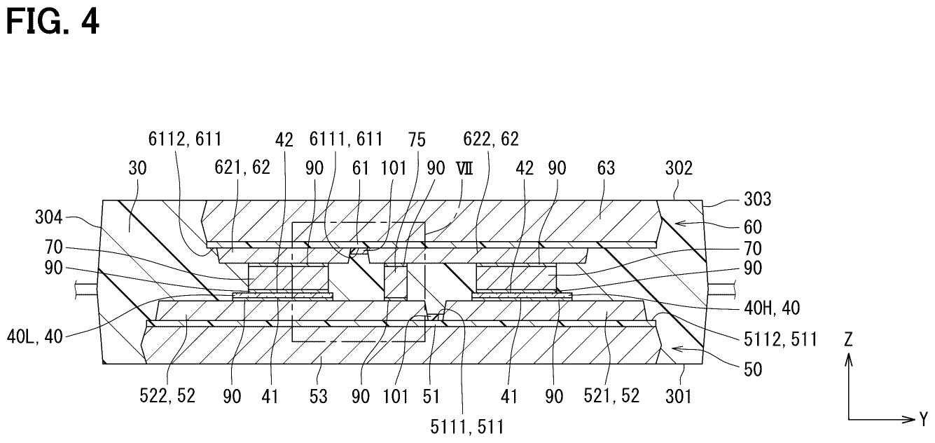

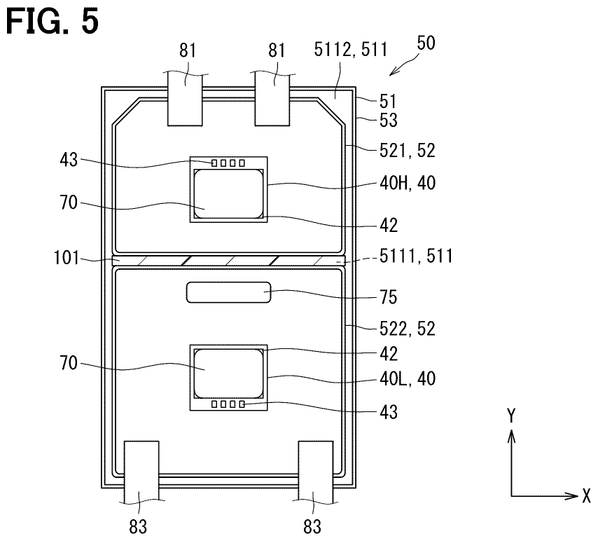

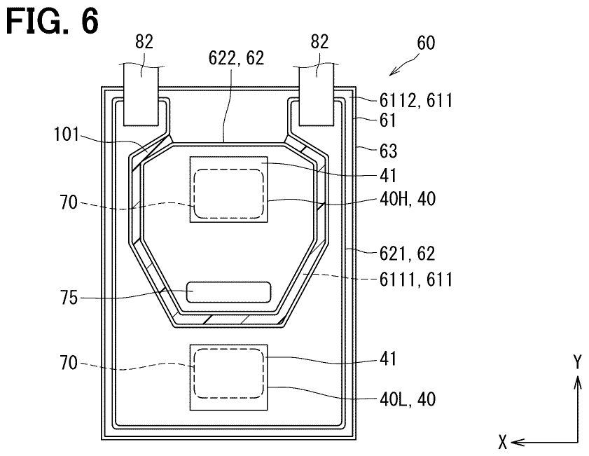

FIG. 2 is a perspective view showing an example of a semiconductor device. FIG. 3 is a three-dimensional cross-sectional view of a semiconductor device. FIG. 3 shows a cross-section taken along a line III-III in FIG. 2. FIG. 4 is a two-dimensional cross-sectional view corresponding to the cross-section shown in FIG. 3. FIG. 5 is a plan view of a substrate on a drain electrode side. FIG. 6 is a plan view of a substrate on a source electrode side. In FIGS. 5 and 6, a front-surface metal body is shown. In FIGS. 5 and 6, a semiconductor element, a conductive spacer, a joint portion, a P terminal, an N terminal, and an O terminal are also shown.

Hereinafter, a thickness direction of the semiconductor element (semiconductor substrate) is defined as a Z direction. A direction orthogonal to the Z direction is defined as a Y direction. A direction orthogonal to both the Z direction and the Y direction is defined as an X direction. The X direction, the Y direction, and the Z direction are in a positional relationship orthogonal to each other. Unless otherwise specified, a shape of an element when viewed in the Z direction, that is, a shape along an XY plane including the X direction and Y direction is referred to as a planar shape., or a shape in a plan view. The plan view when viewed in the Z direction may be simply referred to as the plan view.

A semiconductor device 20 constitutes the upper and lower arm circuit 9, that is, constitutes the inverter 6. The illustrated semiconductor device 20 constitutes one of the upper and lower arm circuits 9, that is, the upper and lower arm circuit 9 for one phase. The semiconductor device 20 may also be referred to as a semiconductor module, a power module, or the like. As shown in FIGS. 2 to 6, the semiconductor device 20 includes a resin molded body 30, a semiconductor element 40, substrates 50 and 60, a conductive spacer 70, a joint portion 75, and an external connection terminal 80.

The resin molded body 30 encapsulates parts of the other elements that constitute the semiconductor device 20. The rest parts of the other elements are exposed to the outside of the resin molded body 30. The resin molded body 30 is made of a resin material. The illustrated resin molded body 30 is made of an epoxy resin and is molded by a transfer molding method. Such a resin molded body 30 may be also referred to as a molded resin, an encapsulating resin body, or the like.

The resin molded body 30 has a generally rectangular shape in the plan view. The resin molded body 30 has a front surface 301, a back surface 302, and side surfaces 303, 304, 305, and 306, as surfaces forming the outer contour. The back surface 302 is a surface opposite to the front surface 301 in the Z direction. The front surface 301 and the back surface 302 are, for example, flat surfaces. The front surface 301 and the back surface 302 will also be referred to as a first surface and a second surface. The side surface 304 is a surface opposite to the side surface 303 in the Y direction. The side surface 306 is a surface opposite to the side surface 305 in the X direction.

The semiconductor element 40 includes a switching element formed on a semiconductor substrate that is made of a material such as silicon (Si), a wide bandgap semiconductor having a wider bandgap than silicon, or the like. Examples of the wide bandgap semiconductor include silicon carbide (SiC), gallium nitride (GaN), gallium oxide (Ga₂O₃) and diamond. The semiconductor element 40 may be also referred to as a power element or a semiconductor chip.

The illustrated semiconductor element 40 is configured by forming the n-channel MOSFET 11 described above in a semiconductor substrate made of SiC. The MOSFET 11 has a vertical structure that causes a main current to flow in the thickness direction of the semiconductor element 40 (semiconductor substrate), that is, in the Z direction. The semiconductor element 40 includes main electrodes of the switching element on both sides of the semiconductor element 40 in the plate thickness direction, that is, in the Z direction. The semiconductor element 40 has, as main electrodes, a drain electrode 41 on the front surface and a source electrode 42 on the back surface. In a case where the diode 12 is a parasitic diode, the source electrode 42 also serves as an anode electrode, and the drain electrode 41 also serves as a cathode electrode. The diode 12 may be formed in a chip separate from the MOSFET 11. The drain electrode 41 is a main electrode on the high potential side, and the source electrode 42 is a main electrode on the low potential side.

The semiconductor element 40 has a substantially rectangular shape in the plan view. The semiconductor element 40 has a pad 43 on the back surface at a position different from the source electrode 42. The source electrode 42 and the pad 43 are exposed from a protective film (not shown) formed on the back surface of the semiconductor substrate. The drain electrode 41 is formed in a substantially entire area on the front surface. The source electrode 42 is formed at a part on the back surface of the semiconductor element 40. The pad 43 is an electrode for a signal. The pad 43 includes a pad for a gate electrode. The illustrated pad 43 is formed at an end opposite to the region where the source electrode 42 is formed in the Y direction.

The semiconductor device 20 includes multiple semiconductor elements 40. The semiconductor device 20 may include multiple types of semiconductor elements with different specifications, as the multiple semiconductor elements 40. Alternatively, all of the semiconductor elements 40 may have a common configuration as in the illustrated semiconductor device 20. The multiple semiconductor elements 40 include a semiconductor element 40H constituting the upper arm 9H and a semiconductor element 40L constituting the lower arm 9L. The semiconductor element 40H may also be referred to as an upper arm element, and the semiconductor element 40L may also be referred to as a lower arm element.

The semiconductor elements 40H and 40L are aligned in the Y direction. The semiconductor elements 40H and 40L are arranged at substantially the same position in the Z-direction. The drain electrodes 41 of the semiconductor elements 40H and 40L face the substrate 50. The source electrodes 42 of the semiconductor elements 40H and 40L face the substrate 60. For example, when the number of switching elements constituting each of the arms 9H and 9L is two, the semiconductor device 20 includes two semiconductor elements 40H and two semiconductor elements 40L. The two semiconductor elements 40H are arranged side by side in the X direction. Similarly, the two semiconductor elements 40L are arranged side by side in the X direction.

The semiconductor element 40H is disposed such that the pad 43 is located on the side surface 303 side with respect to the source electrode 42. The semiconductor element 40L is disposed such that the pad 43 is located on the side surface 304 side with respect to the source electrode 42.

The substrates 50 and 60 are disposed in the Z direction so as to interpose the multiple semiconductor elements 40 therebetween. That is, the substrates 50 and 60 are disposed on opposite sides of the multiple semiconductor elements 40 in the Z direction. The substrates 50 and 60 are disposed so as to face each other at least at a part in the Z direction. The substrates 50 and 60 enclose all of the semiconductor elements 40 in the plan view. The substrate 50 is disposed on the drain electrode 41 side. The substrate 60 is disposed on the source electrode 42 side. The substrate 50 is electrically connected to the drain electrode 41 and provides a wiring function. The substrate 60 is electrically connected to the source electrode 42 and provides a wiring function. The substrates 50 and 60 each provide a heat dissipation function of dissipating heat generated from the semiconductor element 40.

The substrate 50 includes an insulating base material 51, a front-surface metal body 52, and a back-surface metal body 53. The substrate 60 includes an insulating base material 61, a front-surface metal body 62, and a back-surface metal body 63. Each of the insulating base materials 51 and 61 is a resin base material containing resin as a material. The illustrated insulating base materials 51 and 61 each include an epoxy resin as the material. The insulating base material 51 electrically separates the front-surface metal body 52 and the back-surface metal body 53 from each other. The insulating base material 61 electrically separates the front-surface metal body 62 and the back-surface metal body 63 from each other.

The front-surface metal bodies 52 and 62 and the back-surface metal bodies 53 and 63 are provided as metal plates or metal foils. The front-surface metal bodies 52 and 62 and the back-surface metal bodies 53 and 63 are made of a metal having favorable electrical and thermal conductivity, such as Cu or Al. The front- surface metal bodies 52 and 62 are patterned. The front-surface metal bodies 52 and 62 may have a nickel (Ni)-based or Au plating film on the metal surface thereof. The front-surface metal body 52 includes a P wiring 521 and a relay wiring 522. The P wiring 521 and the relay wiring 522 are electrically separated by a predetermined gap (spacing). This gap is filled with the resin molded body 30.

The P wiring 521 is connected to a P terminal 81 and the drain electrode 41 of the semiconductor element 40H. The P wiring 521 electrically connects the P terminal 81 and the drain electrode 41 of the semiconductor element 40H. The relay wiring 522 is connected to the drain electrode 41 of the semiconductor element 40L, the joint portion 75, and an O terminal 83. The relay wiring 522 electrically connects the O terminal 83 and the drain electrode 41 of the semiconductor element 40L. The illustrated P wiring 521 has a substantially rectangular shape in the plan view. The relay wiring 522 has a substantially rectangular shape in the plan view. The P wiring 521 and the relay wiring 522 are arranged side by side in the Y direction.

The P terminal 81 is connected to the P wiring 521 near the end on the side surface 303 side. The O terminal 83 is connected to the relay wiring 522 near the end on the side surface 304 side. The drain electrode 41 of the semiconductor element 40H is connected to the P wiring 521 at a position closer to the relay wiring 522 than a joining portion of the P terminal 81 at which the P terminal 81 is joined to the P wiring 521. The drain electrode 41 of the semiconductor element 40L is connected to the relay wiring 522 at a position closer to the P wiring 521 than a joining portion of the O terminal 83 at which the O terminal 83 is joined to the relay wiring 52. The joint portion 75 is connected to the relay wiring 522 at a position closer to the P wiring 521 than the semiconductor element 40L.

The front-surface metal body 62 includes an N wiring 621 and a relay wiring 622. The N wiring 621 and the relay wiring 622 are electrically separated by a predetermined gap (spacing). This gap is filled with the resin molded body 30. The N wiring 621 is connected to an N terminal 82 and the source electrode 42 of the semiconductor element 40L. The N wiring 621 electrically connects the N terminal 82 and the source electrode 42 of the semiconductor element 40L. The relay wiring 622 is connected to the source electrode 42 of the semiconductor element 40H and the joint portion 75. The relay wiring 622 electrically connects, via the joint portion 75, the source electrode 42 of the semiconductor element 40H and the drain electrode 41 of the semiconductor element 40L.

The illustrated N wiring 621 has a substantially U shape in the plan view. The N wiring 621 has a base portion extending in the X direction and a pair of extension portions that are connected to the base portion and extend in the Y direction from both ends of the base portion. The relay wiring 622 is disposed between the pair of extension portions of the N wiring 621. The relay wiring 622 has a shape that is the same as or similar to a baseball home base in the plan view. The base portion of the N wiring 621 and the relay wiring 622 are arranged side by side in the Y direction. The extension portions of the N wiring 621 and the relay wiring 622 are arranged side by side in the X direction.

The source electrode 42 of the semiconductor element 40L is connected to the base portion of the N wiring 621. The N terminal 82 is connected to the extension portion of the N wiring 621. The semiconductor element 40L is connected to the N wiring 621 near the end on the side surface 304 side. The N terminal 82 is connected to the N wiring 621 near the end on the side surface 303 side. The source electrode 42 of the semiconductor element 40H is connected to the relay wiring 622. The joint portion 75 is connected to the relay wiring 622 at a position closer to the base portion of the N wiring 621 than the semiconductor element 40H.

The back-surface metal bodies 53 and 63 are electrically separated from the front-surface metal bodies 52 and 62 by the insulating base materials 51 and 61, respectively. The illustrated back-surface metal bodies 53 and 63 are so-called solid conductors that are disposed over almost the entire back surfaces of the insulating base materials 51 and 61, respectively. The back-surface metal body 53 is exposed from the front surface 301 of the resin molded body 30, and the back-surface metal body 63 is exposed from the back surface 302 of the resin molded body 30. The back-surface metal body 53 is exposed from the front surface 301 and is substantially coplanar with the front surface 301. The back-surface metal body 63 is exposed from the back surface 302 and is substantially coplanar with the back surface 302.

The conductive spacer 70 provides a spacer function of securing a predetermined interval between the semiconductor element 40 and the substrate 60. The conductive spacer 70 ensures a height for electrically connecting a signal terminal 84 to a corresponding pad 43 of the semiconductor element 40, for example. The conductive spacer 70 is located at an intermediate position on an electrical and thermal conduction path between the source electrode 42 of the semiconductor element 40 and the substrate 60. The conductive spacer 70 provides a wiring function and a heat dissipation function. The conductive spacer 70 includes a metal material, such as Cu, that has favorable electrical and thermal conductivities. The conductive spacer 70 may have a plating film on a surface thereof. The conductive spacer 70 is a columnar body having substantially a rectangular shape in the plan view. The conductive spacer 70 has substantially the same size as the source electrode 42 in the plan view.

The conductive spacer 70 may be also referred to as a terminal, a terminal block, a metal block, or the like. The semiconductor device 20 includes the conductive spacers 70 the number of which is identical to the number of the semiconductor elements 40. Specifically, the semiconductor device 20 includes two conductive spacers 70. One of the conductive spacers 70 electrically connects the source electrode 42 of the semiconductor element 40H and the relay wiring 622. The other conductive spacer 70 electrically connects the source electrode 42 of the semiconductor element 40L and the N wiring 621.

The joint portion 75 electrically connects the relay wiring 522 and the relay wiring 622. In other words, the joint portion 75 electrically connects the upper arm 9H and the lower arm 9L. The joint portion 75 is disposed between the semiconductor element 40H and the semiconductor element 40L. The joint portion 75 is disposed in an overlapping region where the relay wiring 522 and the relay wiring 622 overlap with each other in the plan view. The illustrated joint portion 75 is a metal column provided separately from the front-surface metal bodies 52 and 62. The joint portion 75 extends in the Z direction. One end of the joint portion 75 is connected to the relay wiring 522, and the other end of the joint portion 75 is connected to the relay wiring 622.

The joint portion 75 may be integrally connected to the front-surface metal bodies 52 and 62. That is, the joint portion 75 may be provided integrally with the front- surface metal bodies 52 and 62 as parts of the substrates 50 and 60. A part of the joint portion 75 may be provided as a part of the substrate 50, and another part of the joint portion 75 may be provided as a part of the substrate 60.

The external connection terminal 80 is a terminal for electrically connecting the semiconductor device 20 to an external device. The external connection terminal 80 is made of a metal material with favorable conductivity, such as Cu. The external connection terminal 80 is, for example, a plate member. The external connection terminal 80 may be also referred to as a lead or the like. The external connection terminal 80 includes the P terminal 81, the N terminal 82, the O terminal 83, and the signal terminal 84. The P terminal 81, the N terminal 82, and the O terminal 83 are electrically connected to the main electrodes of the semiconductor element 40, and therefore may be also referred to as main terminals. The P terminal 81 and the N terminal 82 may be also referred to as power supply terminals.

The P terminal 81 is connected to the vicinity of one end of the P wiring 521 in the Y direction. A part of the P terminal 81 is covered with the resin molded body 30, and the other part of the P terminal 81 protrudes to the outside of the resin molded body 30. The joining portion of the P terminal 81 with the P wiring 521 is covered with the resin molded body 30. The illustrated P terminal 81 extends substantially in the Y direction. The P terminal 81 protrudes from the side surface 303. The semiconductor device 20 has two P terminals 81.

The N terminal 82 is connected to the extension portion of the N wiring 621. A part of the N terminal 82 is covered with the resin molded body 30, and the other part of the N terminal 82 protrudes to the outside of the resin molded body 30. The joining portion of the N terminal 82 with the N wiring 621 is covered with the resin molded body 30. The illustrated N terminal 82 extends substantially in the Y direction, which is the same direction as the P terminal 81. The N terminal 82 protrudes from the side surface 303. The semiconductor device 20 includes two N terminals 82 that are individually connected to the extension portions of the N wiring 621.

The O terminal 83 is connected to the vicinity of one end of the relay wiring 522 in the Y direction. A part of the O terminal 83 is covered with the resin molded body 30, and the other part of the O terminal 83 protrudes to the outside of the resin molded body 30. The joining portion of the O terminal 83 with the relay wiring 522 is covered with the resin molded body 30. The illustrated O terminal 83 extends substantially in the Y direction and extends opposite to the P terminal 81 and the N terminal 82. The O terminal 83 protrudes from the side surface 304.

The signal terminal 84 is electrically connected to the pad 43 of the corresponding semiconductor element 40. The signal terminal 84 includes a signal terminal connected to the pad 43 of the semiconductor element 40H and a signal terminal connected to the pad 43 of the semiconductor element 40L. The illustrated signal terminals 84 are connected to the corresponding pads 43 through bonding wires (not shown). The signal terminal 84 extends substantially in the Y direction in the plan view. A part of the signal terminal 84 including the connection portion with the pad 43 is covered by the resin molded body 30, and the other part of the signal terminal 84 protrudes from the resin molded body 30.

The signal terminal 84 connected to the pad 43 of the semiconductor element 40H protrudes from the side surface 303 to the outside of the resin molded body 30. The P terminal 81, the N terminal 82, and the signal terminal 84 the upper arm 9H side are arranged side by side in the X direction. In the X direction, the N terminal 82, the P terminal 81, the signal terminal 84, the P terminal 81, and the N terminal 82 are arranged in this order. The signal terminal 84 connected to the pad 43 of the semiconductor element 40 L protrudes from the side surface 304 to the outside of the resin molded body 30. The O terminal 83 and the signal terminal 84 on the lower arm 9L side are arranged side by side in the X direction. In the X direction, the O terminal 83, the signal terminals 84, and the O terminal 83 are arranged in this order.

The semiconductor device 20 includes a joining material 90. The joining material 90 may be a solder or a sintered material. The drain electrode 41 of the semiconductor element 40 is connected to the front-surface metal body 52 through the joining material 90. The source electrode 42 of the semiconductor element 40 is connected to the conductive spacer 70 through the joining material 90. The conductive spacer 70 is connected to the front-surface metal body 62 through the joining material 90. The joint portion 75 is connected to the front-surface metal bodies 52 and 62 through the joining material 90. The multiple joining materials 90 may be made of a common material, or the material of some of the joining materials 90 may be different from the material of the other joining materials 90.

The P terminal 81, the N terminal 82, and the O terminal 83 may be connected to the corresponding front-surface metal bodies 52 and 62 by the joining materials 90 described above. The P terminal 81, the N terminal 82, and the O terminal 83 may be solid-state bonded to the corresponding front-surface metal bodies 52 and 62. Examples of the solid-state bonding includes ultrasonic bonding, room temperature bonding, friction stir bonding, diffusion bonding, and friction welding.

As described above, in the semiconductor device 20, the resin molded body 30 encapsulates the multiple semiconductor elements 40 constituting the upper and lower arm circuit 9 for one phase. The resin molded body 30 integrally encapsulates the semiconductor elements 40, a part of the substrate 50, a part of the substrate 60, the conductive spacers 70, the joint portion 75, and a part of each of the external connection terminals 80. The resin molded body 30 encapsulates the insulating base materials 51 and 61 and the front-surface metal bodies 52 and 62 of the substrates 50 and 60.

The semiconductor element 40 is disposed between the substrate 50 and the substrate 60 in the Z direction. The semiconductor element 40 is interposed between the substrate 50 and the substrate 60, which are disposed to face each other. Therefore, the heat of the semiconductor element 40 can be dissipated to both sides in the Z-direction. The semiconductor device 20 has a double-sided heat dissipation structure. The back-surface metal body 53 is exposed from the resin molded body 30 and is substantially coplanar with the front surface 301 of the resin molded body 30. The back-surface metal body 63 is exposed from the resin molded body 30 and is substantially coplanar with the back surface 302 of the resin molded body 30. The exposed structure of the back-surface metal bodies 53 and 63 can enhance heat dissipation.

### <Triple Junction, Fragile Layer, and Roughened Part>

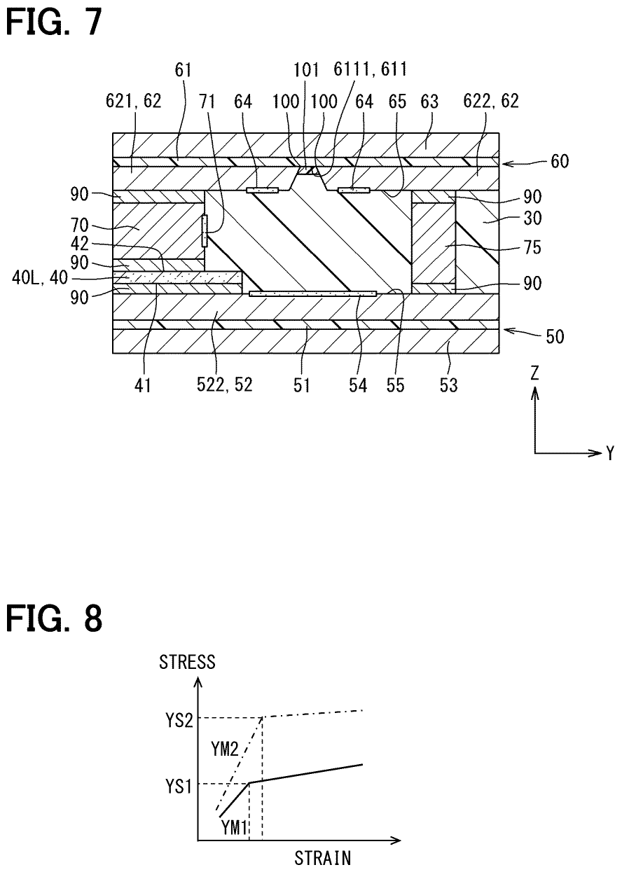

FIGS. 5 and 6 also show a fragile layer. FIG. 7 is an enlarged view of a region VII indicated by the dashed line in FIG. 4. FIG. 8 is a diagram showing the relationship between a stress and a strain of the fragile layer and the insulating base material. In FIG. 8, the fragile layer is indicated by a solid line, and the insulating base material is indicated by a dashed line. In FIGS. 2 to 6, illustration of a roughened portion is omitted for the sake of convenience.

As shown in FIGS. 4, 5 and 7, the insulating base material 51 has an exposed surface 511 exposed from the front-surface metal body 52. The exposed surface 511 has an inter-wiring exposed portion 5111 and an outer peripheral exposed portion 5112. The inter-wiring exposed portion 5111 is a portion exposed due to a gap between the adjacent wirings. The inter-wiring exposed portion 5111 is exposed due to a gap between the P wiring 521 and the relay wiring 522. The outer peripheral exposed portion 5112 is a portion that is exposed from the front-surface metal body 52 at the outer peripheral edge of the insulating base material 51. The outer peripheral exposed portion 5112 is provided along the outer peripheral edge of the insulating base material 51.

As shown in FIGS. 4, 6, and 7, the insulating base material 61 has an exposed surface 611 exposed from the front-surface metal body 62. The exposed surface 611 includes an inter-wiring exposed portion 6111 and an outer peripheral exposed portion 6112. The inter-wiring exposed portion 6111 is a portion exposed due to a gap between the adjacent wirings. The inter-wiring exposed portion 6111 is exposed due to a gap between the N wiring 621 and the relay wiring 622. The outer peripheral exposed portion 6112 is a portion exposed from the front-surface metal body 62 at the outer peripheral edge of the insulating base material 61. The outer peripheral exposed portion 6112 is provided along the outer peripheral edge of the insulating base material 61.

As shown in FIG. 7, the semiconductor device 20 has triple junctions 100 where the resin molded body 30, the insulating base material 61, and the front-surface metal body 62 overlap each other. The triple junctions 100 are formed due to the insulating base material 61 having the exposed surface 611. The triple junctions 100 include a triple junction 100 formed between the resin molded body 30, the insulating base material 61, and the N wiring 621, and a triple junction 100 formed between the resin molded body 30, the insulating base material 61, and the relay wiring 622, on the inter-wiring exposed portion 6111. The triple junctions 100 include a triple junction 100 formed between the resin molded body 30, the insulating base material 61, and the front-surface metal body 62 (N wiring 621) on the outer peripheral exposed portion 6112.

Although not shown, the semiconductor device 20 has triple junctions 100 where the resin molded body 30, the insulating base material 51, and the front-surface metal body 52 overlap each other. The triple junctions 100 include a triple junction 100 formed between the resin molded body 30, the insulating base material 51, and the P wiring 521, and a triple junction 100 formed between the resin molded body 30, the insulating base material 51, and the relay wiring 522, on the inter-wiring exposed portion 5111. The triple junctions 100 include a triple junction 100 formed between the resin molded body 30, the insulating base material 51, and the P wiring 521, and a triple junction 100 formed between the resin molded body 30, the insulating base material 51, and the relay wiring 522, on the outer peripheral exposed portion 5112.

In the above-described configuration having the triple junctions 100, thermal stress is concentrated at the triple junctions 100. The semiconductor device 20 further includes a fragile layer 101 to reduce the thermal stress acting on the triple junctions 100. The fragile layer 101 is stacked on at least a part of each of the exposed surfaces 511 and 611 of the insulating base materials 51 and 61 and is interposed between each of the insulating base materials 51 and 61 and the resin molded body 30. The illustrated fragile layers 101 are disposed on the inter-wiring exposed portions 5111 and 6111.

The fragile layer 101 is a layer that is more fragile than the insulating base materials 51 and 61. As shown in FIG. 8, a yield stress YS1 of the fragile layer 101 is smaller than a yield stress YS2 of the insulating base materials 51 and 61. That is, a yield point of the fragile layer 101 is lower than yield points of the insulating base materials 51 and 61. In addition, a Young's modulus YM1 of the illustrated fragile layer 101 is smaller than a Young's modulus YM2 of the insulating base material 61. The fragile layer 101 is formed using a material having a lower yield point than the insulating base materials 51 and 61 and a smaller Young's modulus than the insulating base material 61. For example, the fragile layer 101 is formed by including any one of polyamideimide, polyamide, and polyimide.

The fragile layer 101 preferably has a glass transition point (Tg) higher than a glass transition point of the resin molded body 30. For this reason, the resin molded body 30 can be formed in a state where the fragile layer 101 has been completely cured. Therefore, it is possible to suppress the decrease in the bulk strength of the fragile layer 101 due to contraction of the resin molded body 30 before a curing treatment, which is caused when the resin molded body 30 is formed in the state where the fragile layer 101 has not been completely cured.

The semiconductor device 20 further includes a lower adhesion portion and a higher adhesion portion. The higher adhesion portion has an adhesion strength to the resin molded body 30 that is higher than an adhesion strength of the lower adhesion portion to the resin molded body 30. The illustrated semiconductor device 20 includes roughened portions 54 and 64 as the higher adhesion portion, and non- roughened portions 55 and 65 as the lower adhesion portion. The substrate 50 has the roughened portion 54 and the non-roughened portion 55. The roughened portion 54 is a portion of the upper surface of the front-surface metal body 52 that is roughened. The non-roughened portion 55 is a portion of the upper surface of the front-surface metal body 52 that is not roughened, that is, a portion excluding the roughened portion 54. The substrate 60 has the roughened portion 64 and the non-roughened portion 65. The roughened portion 64 is a portion of the upper surface of the front-surface metal body 62 that is roughened. The non-roughened portion 65 is a portion of the upper surface of the front-surface metal body 62 that is not roughened, that is, a portion excluding the roughened portion 64. For example, the portions where the bonding materials 90 are disposed are the non-roughened portions 55 and 65.

The roughened portions 54 and 64 can be formed by laser irradiation, blasting, blackening treatment, roughening plating, or the like. The illustrated roughened portions 54 and 64 are roughened by the laser irradiation. The roughened portions 54 and 64 are obtained by irradiating plating films formed on the surfaces of the front-surface metal bodies 52 and 62 with a pulsed laser. The roughened portions 54 and 64 are formed by uneven oxide films having fine irregularities on the surface and being derived from the main metal forming the plating film. As shown in FIG. 7, a similar roughened portion 71 is also provided on the side surface of the conductive spacer 70.

The roughened portion 54 is provided so as to overlap at least a part of the inter-wiring exposed portion 6111 in the plan view in the Z direction. The roughened portion 54 is provided at a position facing the inter-wiring exposed portion 6111. Although not shown, the roughened portion 64 is provided so as to overlap at least a part of the inter-wiring exposed portion 5111 in the plan view. The roughened portion 64 is provided at a position facing the inter-wiring exposed portion 5111. The fragile layer 101 is provided so as to face the roughened portion 54 or 64 in the Z direction. The roughened portion 64 is also formed on the outer peripheral portion of the patterned front-surface metal body 52 or 62.

### <Effects of Fragile Layer>

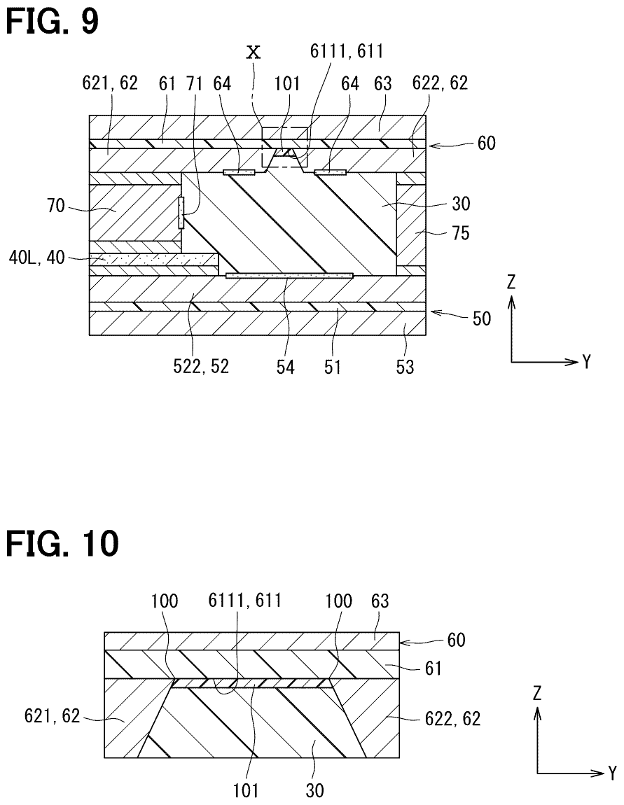

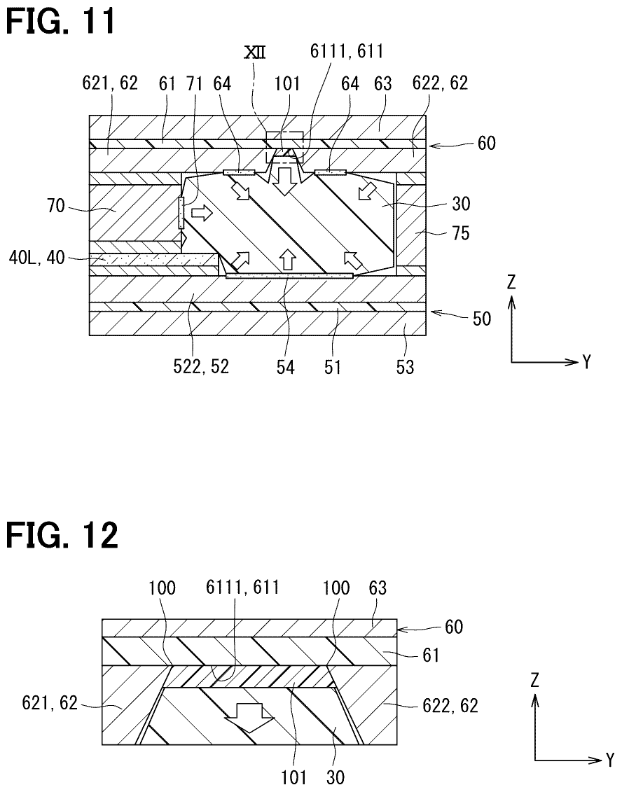

FIG. 9 is a cross-sectional view showing a state in which resin is filled during molding of the resin molded body. FIG. 9 shows the state before contraction. FIG. 10 is an enlarged view of a region X shown in FIG. 9. FIG. 11 is a cross-sectional view showing a contraction state before the curing treatment during the molding of the resin molded body. FIG. 12 is an enlarged view of a region XII shown in FIG. 11. FIGS. 9 and 11 both show the states before the curing treatment.

In the molding of the resin molded body 30, the curing treatment such as heating is necessary to complete the reaction of the unreacted portion. The resin molded body 30 is completely cured by the curing treatment, and the linear expansion coefficient of the resin molded body 30 after the curing treatment becomes smaller than that before the curing treatment. Before the curing treatment, the linear expansion coefficient of the resin molded body 30 is greater than those of the front-surface metal bodies 52 and 62 (wirings) and the insulating base materials 51 and 61 that contain resin.

In the illustrated semiconductor device 20, the linear expansion coefficient of the resin molded body 30 after the curing treatment is about 14×10⁻⁶/K, and the linear expansion coefficient of the resin molded body 30 before the curing treatment is about 20×10⁻⁶/K. The linear expansion coefficients of the insulating base materials 51 and 61 are about 14×10⁻⁶/K, and the linear expansion coefficients of the front-surface metal bodies 52 and 62 are about 16.5×10⁻⁶/K.

The fragile layer 101 is formed by applying any one of polyamideimide, polyamide, and polyimide onto the exposed surfaces 511 and 611 of the insulating base materials 51 and 61 before the resin molded body 30 is formed. The illustrated fragile layer 101 is formed on each of the inter-wiring exposed portions 5111 and 6111. In the state where the fragile layers 101 are formed, the resin is injected into the cavity of a mold (not shown) and pressure is maintained, so that the resin reaches every corner of the cavity as shown in FIGS. 9 and 10. The fragile layer 101 is interposed between the resin molded body 30 and each of the inter-wiring exposed portions 5111 and 6111 of the insulating base materials 51 and 61.

As described above, before the curing treatment, the linear expansion coefficient of the resin molded body 30 is larger than those of the front-surface metal bodies 52 and 62 and the insulating base materials 51 and 61 that contain resin. Therefore, when the temperature of the resin molded body 30 decreases after the pressure is maintained and before the curing treatment is performed, the resin molded body 30 is contracted (thermally contracted) in directions shown by arrows in FIG. 11. The thermal stress is likely to concentrate at the triple junction 100. In particular, the roughened portions 54 and 64 are disposed on the surfaces facing the inter-wiring exposed portions 5111 and 6111. That is, the adhesion strength with the resin molded body 30 is increased. Therefore, the tensile force due to resin contraction increases on the sides to which the roughened portions 54 and 64 face, and the thermal stress is more likely to concentrate at the triple junctions 100.

When the resin molded body 30 contracts, the fragile layer 101, which has a smaller Young's modulus than the insulating base materials 51 and 61, elastically deforms. The fragile layer 101 largely deforms beyond its yield point. That is, the fragile layer 101 largely deforms in the Z direction, as shown in FIG. 12. The fragile layer 101 relieves the tensile force caused by the contraction of the resin.

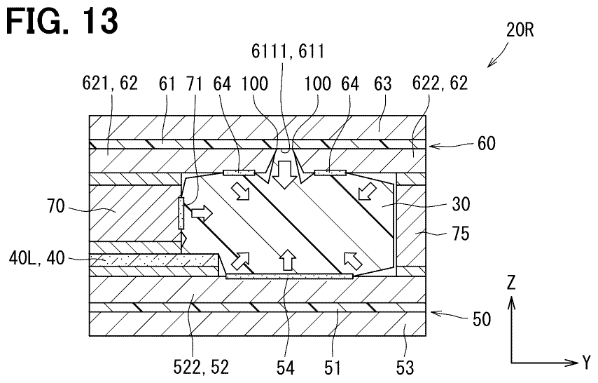

FIG. 13 is a cross-sectional view showing a reference example. FIG. 13 corresponds to FIG. 12. A semiconductor device 20R of the reference example is not provided with the fragile layer 101 on the inter-wiring exposed portion 6111. The other configurations of the reference example are similar to those of the semiconductor device 20. In the structure illustrated in the reference example, when the resin molded body 30 contracts in directions shown by arrows in FIG. 13, the thermal stress concentrates at the triple junctions 100. As a result, cracks or the like may occur in the insulating base materials 51 and 61, for example.

### <Summary of First Embodiment>

The semiconductor device 20 of the present embodiment includes the substrates 50 and 60, the semiconductor element 40, and the resin molded body 30. The insulating base materials 51 and 61 of the substrates 50 and 60 have the exposed surfaces 511 and 611. The semiconductor device 20 has the fragile layers 101 stacked on at least part of the exposed surfaces 511 and 611 and interposed between the insulating base materials 51 and 61 and the resin molded body 30, and the fragile layers 101 have the yield point lower than that of the insulating base materials 51 and 61. Therefore, when the resin molded body 30 contracts before the curing treatment, the fragile layer 101 largely deforms beyond the yield point, that is, plastically deforms. Therefore, it is possible to reduce the thermal stress acting on the insulating base materials 51 and 61.

As illustrated, the Young's modulus of the fragile layer 101 may be smaller than the Young's modulus of the insulating base materials 51 and 61. Since the fragile layer 101 is softer than the insulating base materials 51 and 61, when the resin molded body 30 contracts before the curing treatment, the thermal stress can be reduced by the elastic deformation of the fragile layer 101. Since the semiconductor device 20 is provided with the fragile layer 101 having the lower yield point and the smaller Young's modulus than those of the insulating base materials 51 and 61, the fragile layer 101 can deform in the elastic and plastic regions, effectively reducing the thermal stress acting on the insulating base materials 51 and 61. The Young's modulus of the fragile layer 101 may be equal to or greater than the Young's modulus of the insulating base materials 51 and 61.

As illustrated, in the configuration in which the front-surface metal body 52 or 62 has a first wiring and a second wiring arranged adjacent to the first wiring with a predetermined gap therebetween, the fragile layer 101 may be stacked on the inter- wiring exposed portion 5111 or 6111 exposed by the gap. In the illustrated semiconductor device 20, for example, the P wiring 521 or the N wiring 621 corresponds to the first wiring, and the relay wiring 522 or 622 correspond to the second wiring.

In the inter-wiring exposed portions 5111 and 6111, there are the triple junctions 100 formed between the first wiring, the insulating base materials 51 and 61, and the resin molded body 30, and the triple junctions 100 formed between the second wiring, the insulating base materials 51 and 61, and the resin molded body 30. In addition, since the wirings are located on both sides of the inter-wiring exposed portions 5111 and 6111, the stress is likely to concentrate. However, since the fragile layers 101 are provided, the thermal stress acting on the insulating base materials 51 and 61 in the inter-wiring exposed portions 5111 and 6111 can be reduced.

As illustrated, the substrate may include a first substrate and a second substrate that are disposed to interpose the semiconductor element 40 therebetween. In addition, the first substrate may have the inter-wiring exposed portion, and the second substrate may have the lower adhesion portion and the higher adhesion portion on a surface facing the first substrate. The higher adhesion portion is provided so as to overlap the inter-wiring exposed portion in the plan view and has the greater adhesion strength with the resin molded body than the lower adhesion portion. In the illustrated semiconductor device 20, one of the substrates 50 and 60 corresponds to the first substrate, and the other corresponds to the second substrate.

As described above, if the higher adhesion portion exists on the surface facing the inter-wiring exposed portion, the tensile force acting onto the inter-wiring exposed portion increases. However, by providing the fragile layer 101, the thermal stress acting on the insulating base materials 51 and 61 can be reduced due to the deformation of the fragile layer 101. In the semiconductor device 20 having a double-sided heat dissipation structure, the insulation reliability can be improved.

As illustrated, the higher adhesion portion may be provided by the roughened portions 54 and 64, and the lower adhesion portion may be provided by the non-roughened portions 55 and 65. In the areas where the roughened portions 54 and 64 are provided, the adhesion strength with the resin molded body 30 can be increased.

As illustrated, the fragile layer 101 may contain any of polyamideimide, polyamide, and polyimide. The fragile layer 101 containing any of these resins has the lower yield point than the insulating base materials 51 and 61 containing an epoxy resin. Moreover, the fragile layer 101 has the smaller Young's modulus than the insulating base materials 51 and 61. Therefore, it is possible to achieve the effects as described above.

The semiconductor device 20 of the present embodiment includes the substrates 50 and 60, the semiconductor element 40, and the resin molded body 30. The insulating base materials 51 and 61 of the substrates 50 and 60 have the exposed surfaces 511 and 611. The semiconductor device 20 includes an interposed layer that includes any of polyamideimide, polyamide, and polyimide, and is stacked on at least part of the exposed surface 511 or 611 and is interposed between the insulating base material 51 or 61 and the resin molded body 30. When the resin molded body 30 contracts before the curing treatment, the interposed layer largely deforms beyond the yield point, that is, plastically deforms. Therefore, it is possible to reduce the thermal stress acting on the insulating base material 51 or 61.

### <Modified Examples>

The higher adhesion portion is not limited to the roughened portions 54 and 64. For example, the higher adhesion portion may be provided by an applied material that has better adhesion to the resin molded body 30 than the insulating base materials 51 and 61.

Although an example in which the higher adhesion portion (roughened portions 54 and 64) is provided has been illustrated, the present disclosure is not limited to this example. The semiconductor device 20 may not have the higher adhesion portion.

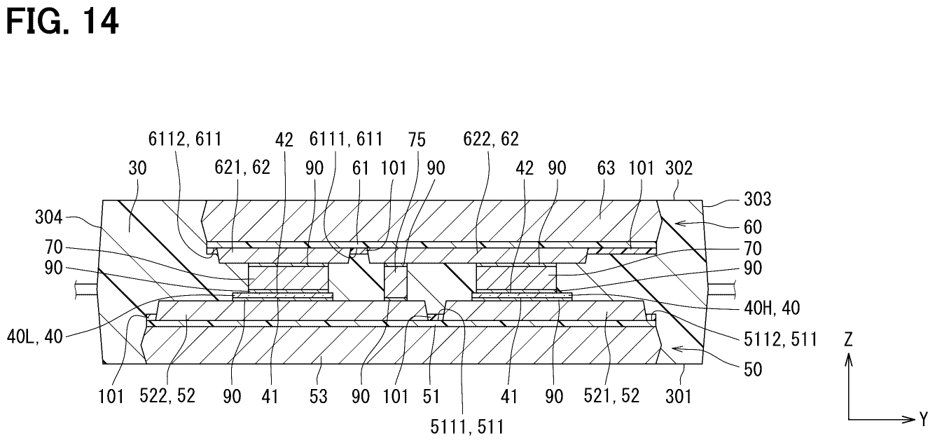

Although an example in which the fragile layers 101 are provided on the inter-wiring exposed portions 5111 and 6111 has been illustrated, the present disclosure is not limited to this example. The fragile layers 101 may be provided on the outer peripheral exposed portions 5112 and 6112. For example, as shown in FIG. 14, the fragile layers 101 may be provided on both the inter-wiring exposed portions 5111 and 6111 and the outer peripheral exposed portions 5112 and 6112. The fragile layer 101 may also be provided on any other surfaces with which the resin molded body 30 comes into contact.

Although an example in which the semiconductor device 20 includes the two substrates 50 and 60 has been illustrated, the present disclosure is not limited to this example. The semiconductor device 20 may include only one substrate. For example, a substrate may be placed on the drain electrode 41 side so that the drain electrode 41 is connected to the first wiring of the substrate, and the source electrode 42 may be connected to the second wiring of the substrate through a metal plate such as a clip or a bonding wire. Since the fragile layer 101 is provided on the inter-wiring exposed portion between the first wiring and the second wiring, when the resin molded body 30 contracts before the curing treatment, the fragile layer 101 deforms largely beyond the yield point, thereby reducing the thermal stress acting on the insulating base material.

### Other Embodiments

The present disclosure in the specification, the drawings and the like is not limited to the embodiments exemplified hereinabove. The present disclosure encompasses the illustrated embodiments and modifications by those skilled in the art based thereon. For example, the present disclosure is not limited to the combinations of components and/or elements shown in the embodiments. The present disclosure may be implemented in various combinations. The present disclosure can have additional parts that can be added to the embodiments. The present disclosure encompasses modifications in which the components and/or the elements of the embodiments are omitted from the embodiments. The present disclosure includes replacements of components and/or elements between one embodiment and another embodiment, or combinations of components and/or elements between one embodiment and another embodiment. The technical scopes disclosed in the present disclosure are not limited to the description of the embodiments. The several technical scopes disclosed are indicated by the description of the claims and should be further understood to include meanings equivalent to the description of the claims and all modifications within the scope.

The present disclosure in the specification, the drawings and the like is not limited by the description of the claims. The present disclosure in the specification, the drawings, and the like encompasses the technical ideas described in the claims, and further extends to a wider variety of technical ideas than those in the claims. Therefore, various technical ideas can be extracted from the disclosure of the specification, the drawings and the like without being limited to the description of the claims.

When an element or a layer is described as “disposed above”, “coupled to” “connected to” or “combined with”, the element or the layer may be directly disposed above, coupled to, connected to, or combined with another element or another layer, or an intervening element or an intervening layer may be present therebetween. In contrast, when an element is described as “directly disposed on”, “directly coupled to”, “directly connected to”, or “directly combined with” another element or another layer, there are no intervening elements or layers present. Other terms used to describe the relationships between elements (for example, “between” vs. “directly between”, and “adjacent” vs. “directly adjacent”) should be interpreted similarly. As used herein, the term “and/or” includes any combination and all combinations relating to one or more of the related listed items. For example, the term A and/or B includes only A, only B, or both A and B. The term A and/or B means at least one of A or B.

Spatial relative terms “inside”, “outside”, “rear”, “bottom”, “low”, “top”, “high”, and the like are used herein to facilitate the description that describes relationships between one element or feature and another element or feature. The spatially relative terms can be intended to include a different orientation of the device in use or operation in addition to the orientation illustrated in each drawing. For example, when the device in the drawing is turned over, an element described as “below” or “immediately below” another element or feature is oriented “above” the other element or feature. Thus, the term “below” can include both orientations of above and below. The device may be oriented in another direction (rotated 90 degrees or in any other direction) and the spatially relative terms used herein are interpreted accordingly.

Although an example in which the semiconductor device 20 is configured as a 2-in-1 package that provides the upper and lower arm circuit 9 for one phase has been illustrated, the present disclosure is not limited to this example. The semiconductor device 20 may be, for example, configured as a 1-in-1 package providing one arm, or a 6-in-1 package.

What is claimed is:

1. A semiconductor device comprising:
a substrate that includes an insulating base material containing a resin, a front-surface metal body disposed on a front surface of the insulating base material and patterned, and a back-surface metal body disposed on a back surface of the insulating base material;
a semiconductor element that has a first main electrode on a first surface and a second main electrode on a second surface opposite to the first surface in a thickness direction of the semiconductor element, and is electrically connected to the front-surface metal body; and
a resin molded body that encapsulates the substrate and the semiconductor element, wherein
the insulating base material has an exposed surface exposed from the front-surface metal body,
the semiconductor device further comprising;
a fragile layer that is stacked on at least a part of the exposed surface, and interposed between the insulating base material and the resin molded body, wherein
the fragile layer has a yield point lower than a yield point of the insulating base material.

2. The semiconductor device according to claim 1, wherein
the fragile layer has a Young's modulus smaller than a Young's modulus of the insulating base material.

3. The semiconductor device according to claim 1, wherein
the front-surface metal body has a first wiring, and a second wiring disposed next to the first wiring with a predetermined gap from the first wiring, and
the fragile layer is stacked on an inter-layer wiring exposed portion that is a part of the exposed surface and exposed by the predetermined gap.

4. The semiconductor device according to claim 3, wherein
the substrate includes a first substrate and a second substrate,
the semiconductor element is disposed between the first substrate and the second substrate in the thickness direction,
the first substrate includes the inter-wiring exposed portion,
the second substrate has a lower adhesion portion and a higher adhesion portion on a surface facing the first substrate,
the higher adhesion portion is disposed to overlap the inter-wiring exposed portion when viewed in the thickness direction, and
an adhesion strength of the higher adhesion portion to the resin molded body is higher than an adhesion strength of the lower adhesion portion to the resin molded body.

5. The semiconductor device according to claim 4, wherein
the higher adhesion portion is a roughened portion, and the lower adhesion portion is a non-roughened portion.

6. The semiconductor device according to claim 1, wherein
the fragile layer contains any of polyamideimide, polyamide, and polyimide.

7. A semiconductor device comprising:
a substrate that includes an insulating base material containing a resin, a front-surface metal body disposed on a front surface of the insulating base material and patterned, and a back-surface metal body disposed on a back surface of the insulating base material;
a semiconductor element that includes a first main electrode on a first surface and a second main electrode on a second surface opposite to the first surface in a thickness direction of the semiconductor element, and is electrically connected to the front-surface metal body; and
a resin molded body that encapsulates the substrate and the semiconductor element, wherein
the insulating base material has an exposed surface exposed from the front-surface metal body,
the semiconductor device further comprising:
an interposed layer that contains any of polyamideimide, polyamide, and polyimide and is stacked on at least a portion of the exposed surface to be disposed between the insulating base material and the resin molded body.
